(19) United States
(12) Patent Application Publication
(10) Pub. No.: US 2023/0291180 A1
(43) Pub. Date: Sep. 14, 2023

(54) QUANTUM CASCADE LASER ELEMENT AND QUANTUM CASCADE LASER DEVICE

(71) Applicant: HAMAMATSU PHOTONICS K.K., Hamamatsu-sh (JP)

(72) Inventor: Atsushi SUGIYAMA, Hamamatsu-shi (JP)

(73) Assignee: HAMAMATSU PHOTONICS K.K., Hamamatsu-shi (JP)

(21) Appl. No.: 18/108,177

(22) Filed: Feb. 10, 2023

(30) Foreign Application Priority Data
Mar. 9, 2022 (JP) 2022-036401

(51) Int. Cl. H01S 5/34; H01S 5/042; H01S 5/323

(52) U.S. Cl. CPC H01S 5/3401; H01S 5/04254; H01S 5/32391

(57) ABSTRACT

A quantum cascade laser element includes: a semiconductor substrate; a semiconductor laminate including an active layer having a quantum cascade structure; a first electrode formed on a surface on an opposite side of the semiconductor laminate from the semiconductor substrate; a second electrode; and an insulating film formed on at least one end surface of a first end surface and a second end surface of the semiconductor laminate. The first electrode includes a first metal layer made of a first metal, and a second metal layer made of a second metal having a higher ionization tendency than that of the first metal. The first metal layer has a first region exposed to an outside. The second metal layer has a second region located on one end surface side with respect to the first region. The insulating film reaches the second region from the one end surface.

### TECHNICAL FIELD

The present disclosure relates to a quantum cascade laser element and a quantum cascade laser device.

### BACKGROUND

In the related art, a quantum cascade laser element has been known which includes a semiconductor substrate; a semiconductor laminate formed on the semiconductor substrate; a first electrode formed on a surface on an opposite side of the semiconductor laminate from the semiconductor substrate; and a second electrode formed on a surface on an opposite side of the semiconductor substrate from the semiconductor laminate, in which a metal film is formed on one end surface of a pair of end surfaces included in the semiconductor laminate including an active layer, with an insulating film interposed therebetween (for example, refer to Japanese Unexamined Patent Publication No. 2019-009225). In such a quantum cascade laser element, since the other end surface of the pair of end surfaces functions as a light-emitting surface while the metal film functions as a reflection film, an efficient light output can be obtained.

### SUMMARY

In the quantum cascade laser element described above, the peeling of an insulating film off from the end surface of the semiconductor laminate may become a problem.

An object of the present disclosure is to provide a quantum cascade laser element and a quantum cascade laser device capable of suppressing peeling of an insulating film off from an end surface of a semiconductor laminate.

A quantum cascade laser element according to one aspect of the present disclosure includes: a semiconductor substrate; a semiconductor laminate formed on the semiconductor substrate, including an active layer having a quantum cascade structure, and having a first end surface and a second end surface facing each other in an optical waveguide direction; a first electrode formed on a surface on an opposite side of the semiconductor laminate from the semiconductor substrate; a second electrode formed on a surface on an opposite side of the semiconductor substrate from the semiconductor laminate; and an insulating film formed on at least one end surface of the first end surface and the second end surface. The first electrode includes a first metal layer made of a first metal, and a second metal layer made of a second metal having a higher ionization tendency than an ionization tendency of the first metal. The first metal layer has a first region exposed to an outside. The second metal layer has a second region located on one end surface side with respect to the first region. The insulating film reaches the second region from the one end surface.

A quantum cascade laser device according to one aspect of the present disclosure includes: the quantum cascade laser element; and a drive unit configured to drive the quantum cascade laser element.

### BRIEF DESCRIPTION OF THE DRAWINGS

FIG. 1 is a cross-sectional view of a quantum cascade laser element of a first embodiment.

FIG. 2 is a cross-sectional view of the quantum cascade laser element taken along line II-II shown in FIG. 1.

FIGS. 3A to 3C are perspective views of a portion of the quantum cascade laser element shown in FIG. 1.

FIGS. 4A and 4B are views showing a method for manufacturing the quantum cascade laser element shown in FIG. 1.

FIGS. 5A and 5B are views showing the method for manufacturing the quantum cascade laser element shown in FIG. 1.

FIGS. 6A and 6B are views showing the method for manufacturing the quantum cascade laser element shown in FIG. 1.

FIG. 7 is a cross-sectional view of a quantum cascade laser device including the quantum cascade laser element shown in FIG. 1.

FIGS. 8A to 8C are perspective views of a portion of a quantum cascade laser element of a second embodiment.

FIG. 9 is a cross-sectional view of a portion of the quantum cascade laser element shown in FIG. 8C.

FIG. 10 is a cross-sectional view of a quantum cascade laser device of a modification example.

FIG. 11 is a cross-sectional view of a portion of a quantum cascade laser element of the modification example.

### DETAILED DESCRIPTION

Hereinafter, embodiments of the present disclosure will be described in detail with reference to the drawings. Incidentally, in the drawings, the same or corresponding portions are denoted by the same reference signs, and duplicated descriptions will not be repeated.

### First Embodiment

### [Configuration of Quantum Cascade Laser Element]

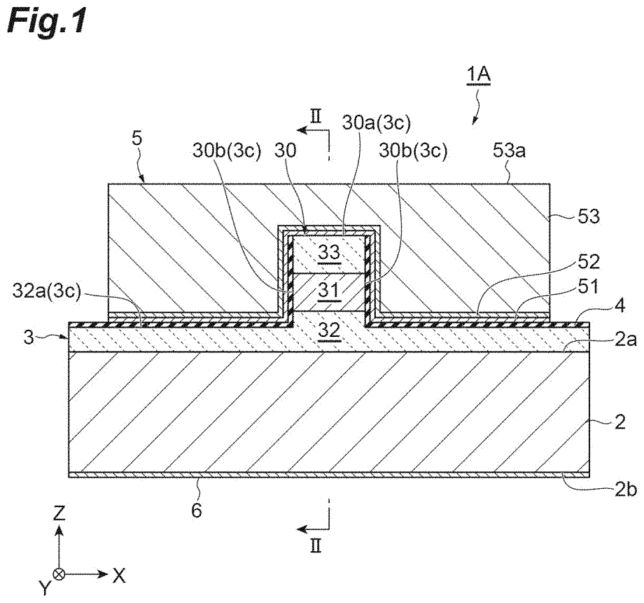

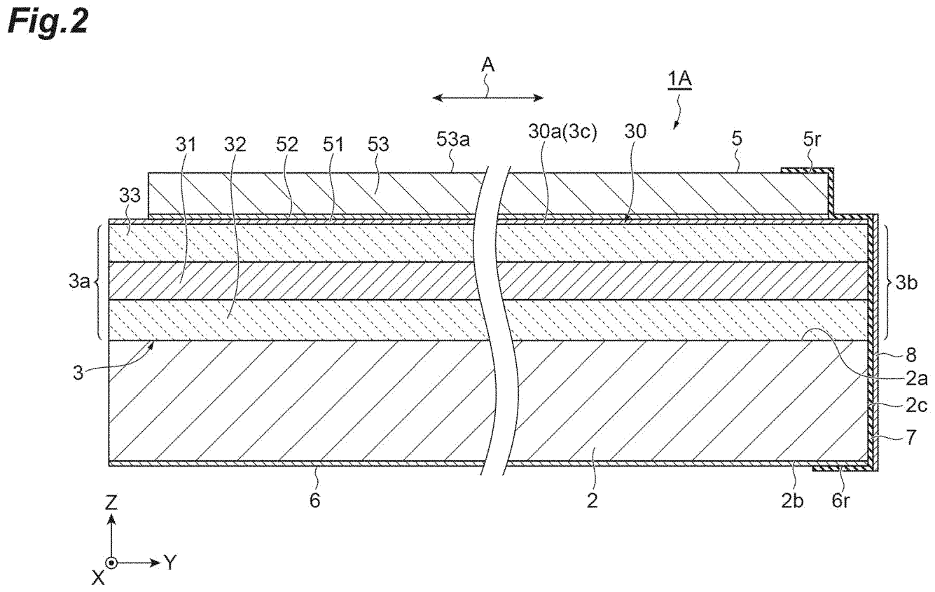

As shown in FIGS. 1 and 2, a quantum cascade laser element 1A includes a semiconductor substrate 2, a semiconductor laminate 3, an insulating film 4, a first electrode 5, a second electrode 6, an insulating film 7, and a metal film 8. The semiconductor substrate 2 is, for example, an N-type InP single crystal substrate having a rectangular plate shape. As one example, a length of the semiconductor substrate 2 is approximately 2 mm, a width of the semiconductor substrate 2 is approximately 500 μm, and a thickness of the semiconductor substrate 2 is approximately one hundred and several tens of μm. In the following description, a width direction of the semiconductor substrate 2 is referred to as an X-axis direction, a length direction of the semiconductor substrate 2 is referred to as a Y-axis direction, and a thickness direction of the semiconductor substrate 2 is referred to as a Z-axis direction.

The semiconductor laminate 3 is formed on a surface 2a of the semiconductor substrate 2. Namely, the semiconductor laminate 3 is formed on the semiconductor substrate 2. The semiconductor laminate 3 includes an active layer 31 having a quantum cascade structure. The semiconductor laminate 3 is configured to oscillate laser light having a predetermined central wavelength (for example, a central wavelength of any value of 4 to 11 μm that is a wavelength in a mid-infrared region). In a first embodiment, the semiconductor laminate 3 is configured by laminating a lower cladding layer 32, a lower guide layer (not shown), the active layer 31, an upper guide layer (not shown), an upper cladding layer 33, and a contact layer (not shown) in order from a semiconductor substrate 2 side. The upper guide layer may have a diffraction grating structure functioning as a distributed feedback (DFB) structure.

The active layer 31 is, for example, a layer having a multiple quantum well structure of InGaAs/InAlAs. Each of the lower cladding layer 32 and the upper cladding layer 33 is, for example, a Si-doped InP layer. Each of the lower guide layer and the upper guide layer is, for example, a Si-doped InGaAs layer. The contact layer is, for example, a Si-doped InGaAs layer.

The semiconductor laminate 3 includes a ridge portion 30 extending along the Y-axis direction. The ridge portion 30 is formed of a portion on an opposite side of the lower cladding layer 32 from the semiconductor substrate 2, the lower guide layer, the active layer 31, the upper guide layer, the upper cladding layer 33, and the contact layer. A width of the ridge portion 30 in the X-axis direction is smaller than a width of the semiconductor substrate 2 in the X-axis direction. A length of the ridge portion 30 in the Y-axis direction is equal to a length of the semiconductor substrate 2 in the Y-axis direction. As one example, the length of the ridge portion 30 is approximately 2 mm, the width of the ridge portion 30 is approximately several μm to ten and several μm, and a thickness of the ridge portion 30 is approximately several μm. The ridge portion 30 is located at a center of the semiconductor substrate 2 in the X-axis direction. Each layer forming the semiconductor laminate 3 does not exist on both sides of the ridge portion 30 in the X-axis direction.

The semiconductor laminate 3 has a first end surface 3a and a second end surface 3b facing each other in an optical waveguide direction A of the ridge portion 30. The optical waveguide direction A is a direction parallel to the Y-axis direction that is an extending direction of the ridge portion 30. The first end surface 3a and the second end surface 3b function as light-emitting end surfaces. The first end surface 3a and the second end surface 3b are located on the same planes as both respective side surfaces of the semiconductor substrate 2 facing each other in the Y-axis direction.

The insulating film 4 is formed on side surfaces 30b of the ridge portion 30 and on a surface 32a of the lower cladding layer 32 such that a surface 30a on an opposite side of the ridge portion 30 from the semiconductor substrate 2 is exposed. The side surfaces 30b of the ridge portion 30 are both respective side surfaces of the ridge portion 30 facing each other in the X-axis direction. The surface 32a of the lower cladding layer 32 is a surface of a portion on an opposite side of the lower cladding layer 32 from the semiconductor substrate 2, the portion not forming the ridge portion 30. The insulating film 4 is, for example, a SiN film or a SiO₂ film.

The first electrode 5 is formed on a surface 3c on an opposite side of the semiconductor laminate 3 from the semiconductor substrate 2. The surface 3c of the semiconductor laminate 3 is a surface formed of the surface 30a of the ridge portion 30, the side surfaces 30b of the ridge portion 30, and the surface 32a of the lower cladding layer 32. The first electrode 5 is in contact with the surface 30a of the ridge portion 30 on the surface 30a of the ridge portion 30, and is in contact with the insulating film 4 on the side surfaces 30b of the ridge portion and on the surface 32a of the lower cladding layer 32. Accordingly, the first electrode 5 is electrically connected to the upper cladding layer 33 through the contact layer.

The second electrode 6 is formed on a surface 2b on an opposite side of the semiconductor substrate 2 from the semiconductor laminate 3. The second electrode 6 is, for example, an AuGe/Au film, an AuGe/Ni/Au film, or an Au film. The second electrode 6 is electrically connected to the lower cladding layer 32 through the semiconductor substrate 2.

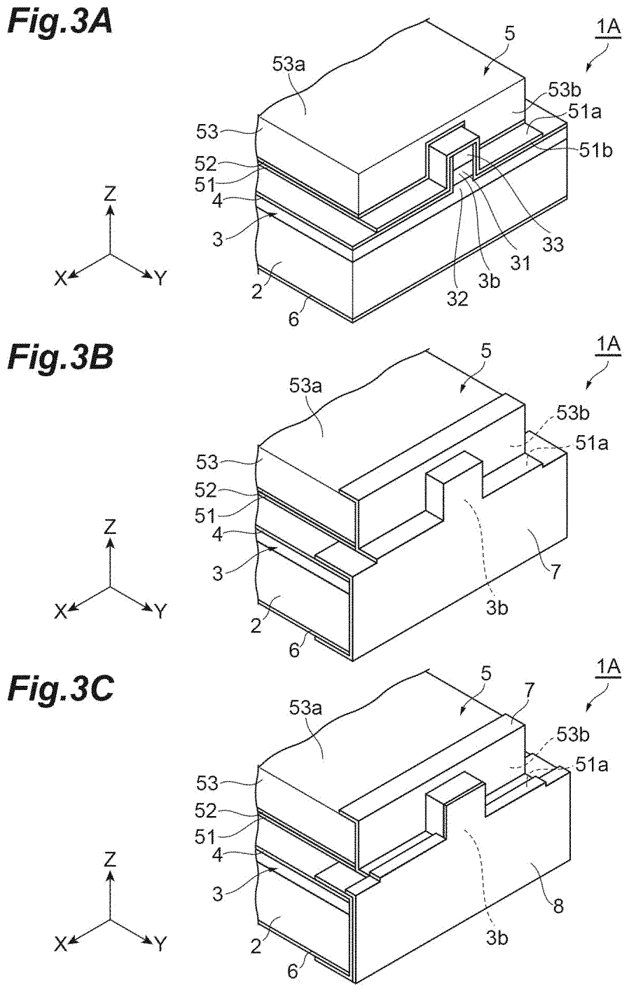

As shown in FIGS. 1, 2, and 3A, the first electrode 5 includes a first foundation layer (second metal layer) 51, a second foundation layer 52, and an electrode layer (first metal layer) 53. Incidentally, in FIG. 3A, the insulating film 7 and the metal film 8 are not shown.

The first foundation layer 51 is formed on the insulating film 4 and on the surface 30a to extend along the surface 3c of the semiconductor laminate 3. When viewed in the Z-axis direction, both side surfaces of the first foundation layer 51 facing each other in the X-axis direction are located inside both respective side surfaces of the semiconductor substrate 2 facing each other in the X-axis direction. When viewed in the Z-axis direction, both side surfaces of the first foundation layer 51 facing each other in the Y-axis direction coincide with both respective side surfaces of the semiconductor substrate 2 facing each other in the Y-axis direction. Namely, both the side surfaces of the first foundation layer 51 facing each other in the Y-axis direction are located on the same planes as the first end surface 3a and the second end surface 3b, respectively. The first foundation layer 51 is a layer made of Ti (second metal). The first foundation layer 51 is formed, for example, by sputtering Ti. A thickness of the first foundation layer 51 is, for example, approximately 50 nm.

The second foundation layer 52 is formed on the first foundation layer 51 to extend along the surface 3c of the semiconductor laminate 3. When viewed in the Z-axis direction, both side surfaces of the second foundation layer 52 facing each other in the X-axis direction coincide with both the respective side surfaces of the first foundation layer 51 facing each other in the X-axis direction. When viewed in the Z-axis direction, both side surfaces of the second foundation layer 52 facing each other in the Y-axis direction are located inside both the respective side surfaces of the first foundation layer 51 facing each other in the Y-axis direction. The second foundation layer 52 is a layer made of Au. The second foundation layer 52 is formed, for example, by sputtering Au. A thickness of the second foundation layer 52 is, for example, approximately 150 nm.

The electrode layer 53 is formed on the second foundation layer 52 such that the ridge portion 30 is embedded in the electrode layer 53. Namely, the electrode layer 53 is disposed on the first foundation layer 51 with the second foundation layer 52 interposed therebetween. When viewed in the Z-axis direction, both side surfaces of the electrode layer 53 facing each other in the X-axis direction coincide with both the respective side surfaces of the second foundation layer 52 facing each other in the X-axis direction. When viewed in the Z-axis direction, both side surfaces of the electrode layer 53 facing each other in the Y-axis direction coincide with both the respective side surfaces of the second foundation layer 52 facing each other in the Y-axis direction.

The electrode layer 53 is a layer made of Au (first metal). The electrode layer 53 is formed, for example, by plating Au. Incidentally, the fact that the ridge portion 30 is embedded in the electrode layer 53 means that the ridge portion 30 is covered with the electrode layer 53 in a state where a thickness of portions of the electrode layer 53 located on both sides of the ridge portion 30 in the X-axis direction (thickness of the portions in the Z-axis direction) is larger than the thickness of the ridge portion 30 in the Z-axis direction.

A surface on an opposite side of the electrode layer 53 from the semiconductor substrate 2 includes a region (first region) 53a exposed to the outside. Namely, the electrode layer 53 has a region 53a exposed to the outside. As one example, the surface on the opposite side of the electrode layer 53 from the semiconductor substrate 2 is a polished surface (flat surface perpendicular to the Z-axis direction) that is flattened by chemical mechanical polishing, and polishing marks are formed in the region 53a.

In the first electrode 5 configured as described above, as shown in FIG. 3A, the first foundation layer 51 has a region (second region) 51a. The region 51a is a part of a surface on an opposite side of the first foundation layer 51 from the semiconductor substrate 2, and is located on a second end surface 3b side with respect to the region 53a of the electrode layer 53 in the Y-axis direction. An edge portion 51b on the second end surface 3b side of the first foundation layer 51 is located on the second end surface 3b side with respect to the region 53a of the electrode layer 53 in the Y-axis direction. In the first embodiment, an edge portion on the second end surface 3b side of the region 51a of the first foundation layer 51 corresponds to the edge portion 51b of the first foundation layer 51, and is located on a plane including the second end surface 3b. The region 51a of the first foundation layer 51 is in a relationship of intersection with a region 53b on the second end surface 3b side of the side surface of the electrode layer 53. Incidentally, a relationship in which one region intersects the other region includes a state where the one region intersects the other region, a state where the one region intersects a surface including the other region, a state where a surface including the one region intersects the other region, and a state where a surface including the one region intersects a surface including the other region.

As described above, the first foundation layer 51 is a layer made of Ti (second metal), and the electrode layer 53 is a layer made of Au (first metal). Ti is a metal having a higher ionization tendency than that of Au. The first foundation layer 51 has a property of having a higher force of adhesion to an oxide than that of the electrode layer 53. The electrode layer 53 has a property of being less likely to be oxidized than the first foundation layer 51. Incidentally, the fact that “the second metal is a metal having a higher ionization tendency than that of the first metal” means that “the second metal is a metal that releases electrons more easily than the first metal”, and means that “the second metal is a metal that is more easily oxidized than the first metal”. Oxidation of metal in the atmosphere occurs when oxygen is adsorbed on a surface of the metal. Specifically, when oxygen having a high electronegativity takes away electrons from the surface of the metal, an oxide layer is formed on the surface of the metal. For this reason, a metal that easily releases electrons can be said to be a metal that is easily oxidized. Namely, a metal having a high ionization tendency can be said to be a metal having a high affinity with oxygen. As described above, a metal that is easily oxidized (namely, a metal having a high ionization tendency) has a higher affinity with an oxide and a higher force of adhesion to an oxide than those of a metal for which it is difficult to be oxidized (namely, a metal having a low ionization tendency).

As shown in FIGS. 2 and 3B, the insulating film 7 is formed on the second end surface 3b. In the first embodiment, the insulating film 7 reaches a region 5r of the first electrode 5 from the second end surface 3b via the region 51a of the first foundation layer 51 and via the region 53b of the electrode layer 53, and reaches a region 6r of the second electrode 6 from the second end surface 3b via a side surface 2c on the second end surface 3b side of the semiconductor substrate 2. The region 5r of the first electrode 5 is a region on the second end surface 3b side of the surface on the opposite side of the electrode layer 53 from the semiconductor substrate 2. The region 6r of the second electrode 6 is a region on the second end surface 3b side of a surface on the opposite side of the second electrode 6 from the semiconductor substrate 2. As described above, the insulating film 7 reaches the electrode layer 53 from the second end surface 3b via the region 51a of the first foundation layer 51, and is in contact with the region 51a of the first foundation layer 51 and with the region 53b of the electrode layer 53. In the first embodiment, the insulating film 7 covers the entirety of the region 51a of the first foundation layer 51. Incidentally, in FIG. 3B, the metal film 8 is not shown.

As shown in FIGS. 2 and 3C, the metal film 8 is formed on the insulating film 7 to overlap at least a part of the active layer 31 when viewed in the optical waveguide direction A. In the first embodiment, the metal film 8 includes the entirety of the active layer 31 when viewed in the optical waveguide direction A, and is formed only on the insulating film 7 to extend along the second end surface 3b of the semiconductor laminate 3, along the side surface 2c of the semiconductor substrate 2, and along the region 51a of the first foundation layer 51. A width of the metal film 8 in the optical waveguide direction A on the ridge portion 30 (namely, on the surface 30a of the ridge portion 30 (refer to FIG. 1)) is smaller than a width of the metal film 8 in the optical waveguide direction A on the portions on both sides of the ridge portion 30 (namely, on the surface 32a of the lower cladding layer 32 (refer to FIG. 1)). In the first embodiment, the width of the metal film 8 in the optical waveguide direction A on the ridge portion 30 is 0.

In the first embodiment, the insulating film 7 is an Al₂O₃ film or a CeO₂ film, and the metal film 8 is an Au film. When the semiconductor laminate 3 is configured to oscillate laser light having a central wavelength of any value of 4 to 7.5 μm, it is preferable that the insulating film 7 is an Al₂O₃ film having a property of transmitting light having a wavelength of 4 to 7.5 μm. When the semiconductor laminate 3 is configured to oscillate laser light having a central wavelength of any value of 7.5 to 11 μm, it is preferable that the insulating film 7 is a CeO₂ film having a property of transmitting light having a wavelength of 7.5 to 11 μm. When the semiconductor laminate 3 is configured to oscillate laser light having a central wavelength of any value of 4 to 11 μm, it is preferable that the metal film 8 is an Au film that effectively functions as a reflection film for reflecting light having a wavelength of 4 to 11 μm.

In the quantum cascade laser element 1A configured as described above, when a bias voltage is applied to the active layer 31 through the first electrode 5 and through the second electrode 6, light is emitted from the active layer 31, and light having a predetermined central wavelength of the light is oscillated in the distributed feedback structure. At this time, the metal film 8 formed on the second end surface 3b functions as a reflection film. Accordingly, the first end surface 3a functions as a light-emitting surface, and the laser light having the predetermined central wavelength is emitted from the first end surface 3a.

### [Method for Manufacturing Quantum Cascade Laser Element]

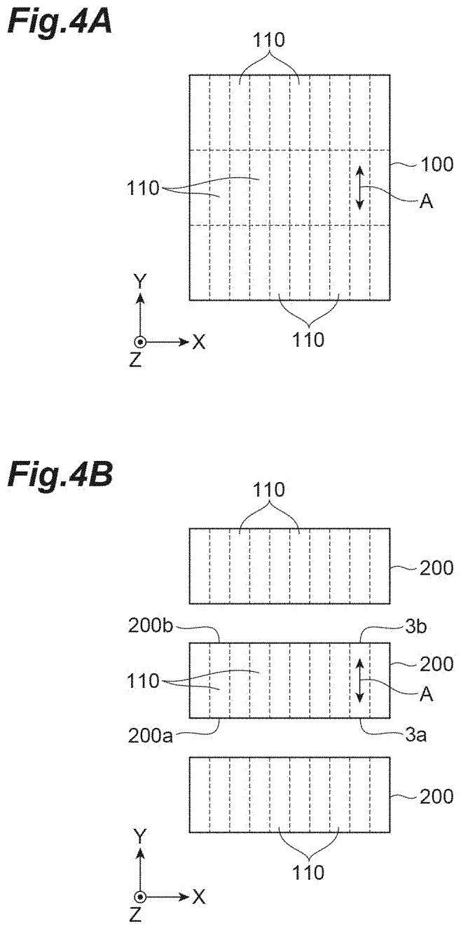

First, as shown in FIG. 4A, a wafer 100 is prepared. The wafer 100 includes a plurality of portions 110 each becoming one set of the semiconductor substrate 2, the semiconductor laminate 3, the insulating film 4, the first electrode 5, and the second electrode 6. In the wafer 100, the plurality of portions 110 are arranged in a matrix pattern with the X-axis direction set as a row direction and with the Y-axis direction (namely, a direction parallel to the optical waveguide direction A in each of the portions 110) set as a column direction. As one example, the wafer 100 is manufactured by the following method.

First, a semiconductor layer including a plurality of portions each becoming the semiconductor laminate 3 is formed on a surface of a semiconductor wafer including a plurality of portions each becoming the semiconductor substrate 2. Subsequently, a part of the semiconductor layer is removed by etching such that each of the plurality of portions of the semiconductor layer each becoming the semiconductor laminate 3 includes the ridge portion 30. Subsequently, an insulating layer including a plurality of portions each becoming the insulating film 4 is formed on the semiconductor layer such that the surface 30a of each of the ridge portions 30 is exposed. Subsequently, a continuous first foundation layer including a plurality of portions each becoming the first foundation layer 51 is formed to cover the surface 30a of each of the ridge portions 30 and to cover the insulating layer. Subsequently, a continuous second foundation layer including a plurality of portions each becoming the second foundation layer 52 is formed on the continuous first foundation layer. Subsequently, a plurality of electrode layers each becoming the electrode layer 53 are formed on the continuous second foundation layer, and the ridge portion is embedded in each of the electrode layers. Subsequently, a surface of each of the electrode layers is flattened by polishing, and a plurality of the electrode layers 53 are formed. Subsequently, portions of the continuous second foundation layer that are exposed between the electrode layers 53 adjacent to each other are removed by etching, and a plurality of the second foundation layers 52 are formed. Subsequently, portions of the continuous first foundation layer that are exposed between the electrode layers 53 adjacent to each other in the X-axis direction are removed by etching. At this time, portions of the continuous first foundation layer that are exposed between the electrode layers 53 adjacent to each other in the Y-axis direction are left. Subsequently, the semiconductor wafer is thinned by polishing a back surface of the semiconductor wafer, and an electrode layer including a plurality of portions each becoming the second electrode 6 is formed on the back surface of the semiconductor wafer.

When the wafer 100 is prepared as described above, as shown in FIG. 4B, a plurality of laser bars 200 are obtained by cleaving the wafer 100 along the X-axis direction. Each of the laser bars 200 includes the plurality of portions 110. In each of the laser bars 200, the plurality of portions 110 are one-dimensionally arranged in the X-axis direction (namely, a direction perpendicular to the optical waveguide direction A in each of the portions 110). Each of the laser bars 200 has a pair of end surfaces 200a and 200b facing each other in the Y-axis direction. The end surface 200a includes a plurality of the first end surfaces 3a that are one-dimensionally arranged along the X-axis direction, and the end surface 200b includes a plurality of the second end surfaces 3b that are one-dimensionally arranged along the X-axis direction.

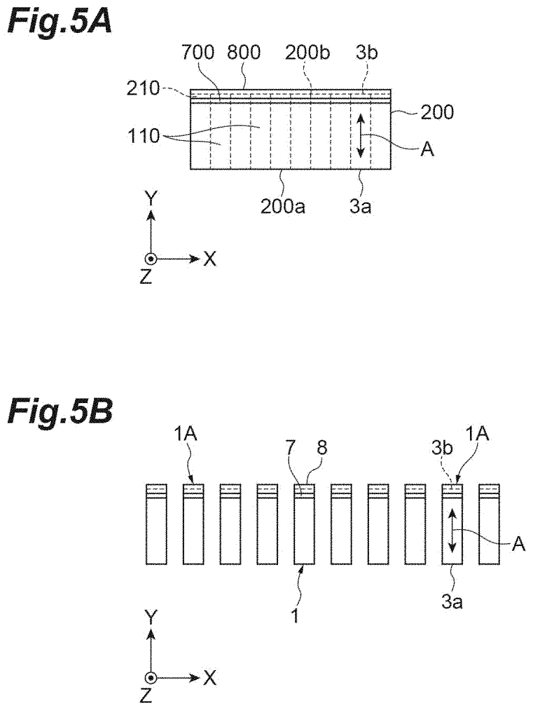

Subsequently, as shown in FIG. 5A, an insulating layer 700 is formed on a surface of a portion 210 of the laser bar 200, the portion 210 including the end surface 200b, and a metal layer 800 is formed on the insulating layer 700. The insulating layer 700 includes a plurality of portions each becoming the insulating film 7. The metal layer 800 includes a plurality of portions each becoming the metal film 8. Subsequently, as shown in FIG. 5B, the laser bar 200, the insulating layer 700, and the metal layer 800 are divided for each of the plurality of portions 110 by cleaving the laser bar 200 along the Y-axis direction, and a plurality of the quantum cascade laser elements 1A are obtained.

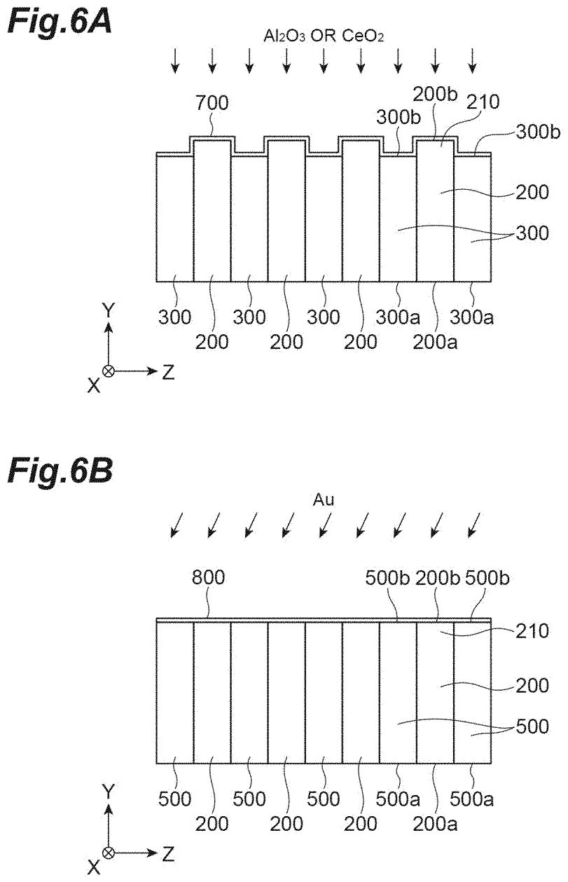

The formation of the insulating layer 700 and the metal layer 800 on the laser bar 200 will be described in more detail. First, as shown in FIG. 6A, a plurality of the laser bars 200 and a plurality of dummy bars 300 are prepared. A length of the dummy bars 300 in the Y-axis direction is shorter than a length of the laser bars 200 in the Y-axis direction. A length of the dummy bars 300 in the X-axis direction is equal to or larger than a length of the laser bars 200 in the X-axis direction.

Subsequently, in a state where the end surface 200a of each of the laser bars 200 and an end surface 300a of each of the dummy bars 300 (one end surface of each of the dummy bars 300 in the Y-axis direction) are disposed on the same plane, the laser bars 200 and the dummy bars 300 are alternately arranged to be adjacent to each other in the Z-axis direction, and the plurality of laser bars 200 and the plurality of dummy bars 300 are held by a holding member (not shown).

Accordingly, the portion 210 of each of the laser bars 200 protrudes from an end surface 300b of the dummy bar 300 adjacent thereto (the other end surface of each of the dummy bars 300 in the Y-axis direction). The insulating layer 700 is formed on the surface of the portion 210 of each of the laser bars 200 by performing sputtering of Al₂O₃ or CeO₂ in this state.

Subsequently, as shown in FIG. 6B, a plurality of dummy bars 500 are prepared. A length of the dummy bars 500 in the Y-axis direction is equal to the length of the laser bars 200 in the Y-axis direction. A length of the dummy bars 500 in the X-axis direction is equal to or larger than the length of the laser bars 200 in the X-axis direction. Incidentally, in FIG. 6B, the insulating layer 700 formed on the surface of the portion 210 of each of the laser bars 200 is not shown.

Subsequently, in a state where the end surface 200a of each of the laser bars 200 and an end surface 500a of each of the dummy bars 500 (one end surface of each of the dummy bars 500 in the Y-axis direction) are disposed on the same plane, the laser bars 200 and the dummy bars 500 are alternately arranged to be adjacent to each other in the Z-axis direction, and the plurality of laser bars 200 and the plurality of dummy bars 500 are held by the holding member (not shown). Accordingly, the insulating layer 700 formed on the surface of the portion 210 of each of the laser bars 200 is located on a plane including an end surface 500b of the dummy bar 500 adjacent thereto (the other end surface of each of the dummy bars 500 in the Y-axis direction). The metal layer 800 is formed on the insulating layer 700 by obliquely performing sputtering of Au in this state. In the first embodiment, the sputtering of Au is performed on each of the laser bars 200 such that the closer the metal layer 800 is to the surface of the insulating layer 700, the further the metal layer 800 is separated from a portion becoming the second electrode 6 and the closer the metal layer 800 is to a portion becoming the first electrode 5. Accordingly, in the quantum cascade laser element 1A that is manufactured, the width of the metal film 8 in the optical waveguide direction A on the ridge portion 30 is smaller than the width of the metal film 8 in the optical waveguide direction A on the portions on both sides of the ridge portion 30.

### [Configuration of Quantum Cascade Laser Device]

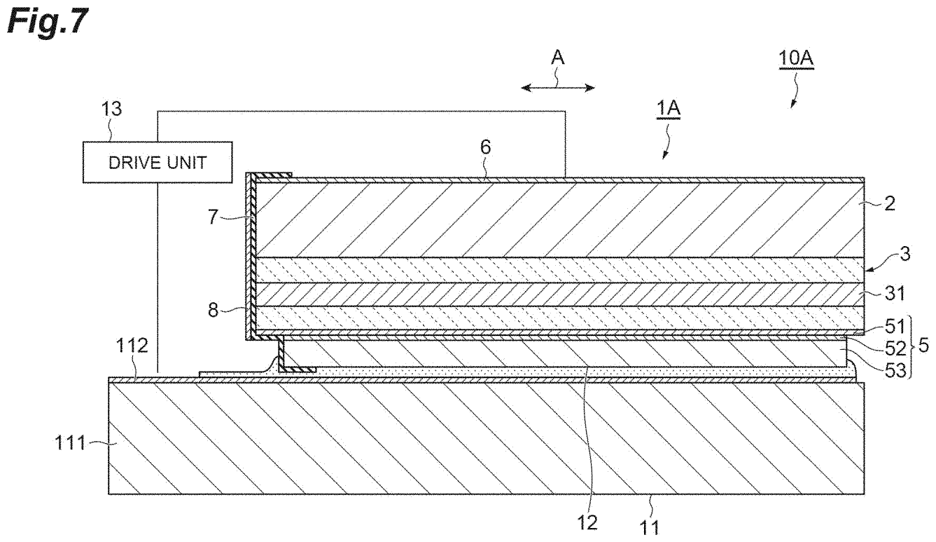

As shown in FIG. 7, a quantum cascade laser device 10A includes the quantum cascade laser element 1A, a support portion 11, a joining member 12, and a drive unit 13. The support portion 11 supports the quantum cascade laser element 1A in a state where the semiconductor laminate 3 is located on a support portion 11 side with respect to the semiconductor substrate 2 (namely, an epi-side-down state).

The support portion 11 includes a body portion 111, and an electrode pad 112 formed on a major surface of the body portion 111. For example, the body portion 111 is formed in a rectangular plate shape from AIN. The electrode pad 112 is, for example, a Ti/Pt/Au film or a Ti/Pd/Au film, and is formed in a rectangular film shape. The support portion 11 is a sub-mount, and is thermally connected to a heat sink (not shown).

The joining member 12 joins the electrode pad 112 of the support portion 11 and the first electrode 5 of the quantum cascade laser element 1A in the epi-side-down state. The joining member 12 is, for example, a solder member such as an AuSn member.

The drive unit 13 drives the quantum cascade laser element 1A such that the quantum cascade laser element 1A continuously oscillates laser light. The drive unit 13 is electrically connected to each of the electrode pad 112 of the support portion 11 and the second electrode 6 of the quantum cascade laser element 1A. In order to electrically connect the drive unit 13 to each of the electrode pad 112 and the second electrode 6, wire bonding is performed on each of the electrode pad 112 and the second electrode 6.

### [Actions and Effects]

In the quantum cascade laser element 1A, the first electrode 5 includes the electrode layer 53 made of Au, and the first foundation layer 51 made of Ti having a higher ionization tendency than that of Au, and the insulating film 7 formed on the second end surface 3b of the semiconductor laminate 3 reaches the region 51a of the first foundation layer 51 from the second end surface 3b. Accordingly, it is possible to sufficiently ensure adhesion between the first foundation layer 51 and the insulating film 7 in the region 51a located on the second end surface 3b side with respect to the region 53a, while suppressing oxidation of the electrode layer 53 in the region 53a exposed to the outside. Therefore, according to the quantum cascade laser element 1A, it is possible to suppress peeling of the insulating film 7 off from the second end surface 3b of the semiconductor laminate 3.

Particularly, in the quantum cascade laser element 1A, since the insulating film 7 reaches the electrode layer 53 in a state where the insulating film 7 covers the entirety of the region 51a of the first foundation layer 51, it is possible to reliably suppress oxidation of the first foundation layer 51.

In the quantum cascade laser element 1A, the electrode layer 53 is disposed on the first foundation layer 51, and the edge portion 51b of the first foundation layer 51 is located on the second end surface 3b side with respect to the region 53a of the electrode layer 53. Accordingly, the region 51a for ensuring adhesion between the first foundation layer 51 and the insulating film 7 can be reliably provided in the vicinity of the second end surface 3b side.

In the quantum cascade laser element 1A, the insulating film 7 reaches the region 53b of the side surface of the electrode layer 53, the region 53b being in a relationship of intersection with the region 51a of the first foundation layer 51. Accordingly, since a part of the insulating film 7 comes into contact with at least a pair of regions that are in a relationship of intersection in the first electrode 5, it is possible to more sufficiently ensure adhesion between the first electrode 5 and the insulating film 7.

In the quantum cascade laser element 1A, the metal film 8 is formed on the insulating film 7 to overlap at least a part of the active layer 31 when viewed in the optical waveguide direction A. Accordingly, it is possible to obtain an efficient light output by causing the metal film 8 on the second end surface 3b to function as a reflection film, and by causing the first end surface 3a opposite the second end surface 3b to function as a light-emitting surface.

In the quantum cascade laser element 1A, the semiconductor laminate 3 includes the ridge portion 30. Accordingly, it is possible to reduce electric power consumption of the quantum cascade laser element 1A by reducing a driving current of the quantum cascade laser element 1A.

In the quantum cascade laser element 1A, the width of the metal film 8 in the optical waveguide direction A on the ridge portion 30 is 0. Accordingly, it is possible to reliably suppress occurrence of a short circuit in the ridge portion 30 caused by the metal film 8. Incidentally, when the width of the metal film 8 in the optical waveguide direction A on the ridge portion 30 is smaller than the width of the metal film 8 in the optical waveguide direction A on the portions on both sides of the ridge portion 30, it is possible to suppress occurrence of a short circuit in the ridge portion 30 caused by the metal film 8.

In the quantum cascade laser element 1A, the insulating film 7 is an Al₂O₃ film or a CeO₂ film. When the insulating film 7 is an Al₂O₃ film, it is possible to ensure a property of transmitting laser light having a central wavelength of 7.5 μm or less. When the insulating film 7 is a CeO₂ film, it is possible to ensure a property of transmitting laser light having a central wavelength of 7.5 μm or more.

According to the quantum cascade laser device 10A, it is possible to suppress peeling of the insulating film 7 off from the end surface of the semiconductor laminate 3 in the quantum cascade laser element 1A.

In the quantum cascade laser device 10A, in the epi-side-down state, the quantum cascade laser element 1A is supported by the support portion 11, and the electrode pad 112 of the support portion 11 and the first electrode 5 of the quantum cascade laser element 1A are joined to each other by the joining member 12. Accordingly, heat generated in the active layer 31 can be efficiently released to the support portion 11 side.

In the quantum cascade laser device 10A, the drive unit 13 drives the quantum cascade laser element 1A such that the quantum cascade laser element 1A continuously oscillates laser light. When the quantum cascade laser element 1A continuously oscillates laser light, the amount of heat generated in the active layer 31 is increased compared to when the quantum cascade laser element 1A oscillates laser light in a pulsed manner, so that the above-described configuration of the quantum cascade laser element 1A is particularly effective.

### Second Embodiment

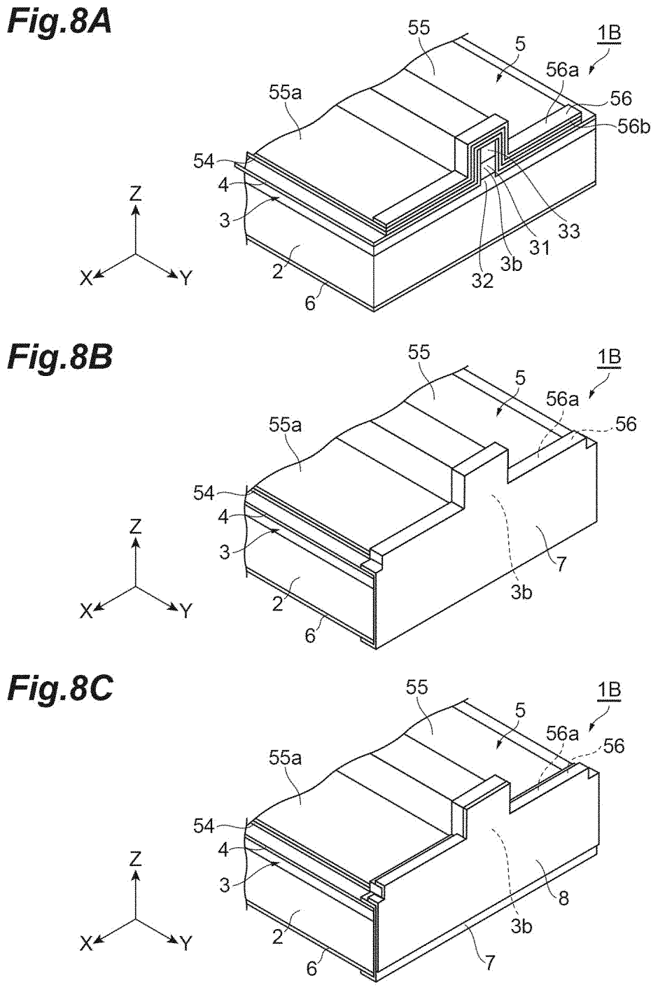

As shown in FIGS. 8A to 8C, a quantum cascade laser element 1B mainly differs from the quantum cascade laser element 1A described above in the configuration of the first electrode 5. Hereinafter, a configuration of the quantum cascade laser element 1B that differs from the configuration of the quantum cascade laser element 1A will be described. Incidentally, since the configurations of the semiconductor substrate 2, the semiconductor laminate 3, the insulating film 4, and the second electrode 6 in the quantum cascade laser element 1B are the same as the configurations of the semiconductor substrate 2, the semiconductor laminate 3, the insulating film 4, and the second electrode 6 in the quantum cascade laser element 1A, in the following description, FIGS. 1 and 2 will be referred to as appropriate.

As shown in FIGS. 1, 2, and 8A, the first electrode 5 of the quantum cascade laser element 1B includes a foundation layer 54, an electrode layer (first metal layer) 55, and an additional layer (second metal layer) 56. Incidentally, in FIG. 8A, the insulating film 7 and the metal film 8 are not shown.

The foundation layer 54 is formed on the insulating film 4 and on the surface 30a to extend along the surface 3c of the semiconductor laminate 3. When viewed in the Z-axis direction, both side surfaces of the foundation layer 54 facing each other in the X-axis direction are located inside both the respective side surfaces of the semiconductor substrate 2 facing each other in the X-axis direction. When viewed in the Z-axis direction, both side surfaces of the foundation layer 54 facing each other in the Y-axis direction coincide with both the respective side surfaces of the semiconductor substrate 2 facing each other in the Y-axis direction. Namely, both the side surfaces of the foundation layer 54 facing each other in the Y-axis direction are located on the same planes as the first end surface 3a and the second end surface 3b, respectively. The foundation layer 54 is a layer made of Ti. The foundation layer 54 is formed, for example, by sputtering Ti. A thickness of the foundation layer 54 is, for example, approximately 50 nm.

The electrode layer 55 is formed on the foundation layer 54 to extend along the surface 3c of the semiconductor laminate 3. When viewed in the Z-axis direction, both side surfaces of the electrode layer 55 facing each other in the X-axis direction coincide with both the respective side surfaces of the foundation layer 54 facing each other in the X-axis direction. When viewed in the Z-axis direction, both side surfaces of the electrode layer 55 facing each other in the Y-axis direction coincide with both the respective side surfaces of the foundation layer 54 facing each other in the Y-axis direction. Namely, both the side surfaces of the electrode layer 55 facing each other in the Y-axis direction are located on the same planes as the first end surface 3a and the second end surface 3b, respectively. A surface on an opposite side of the electrode layer 55 from the semiconductor substrate 2 includes a region (first region) 55a exposed to the outside. Namely, the electrode layer 55 has the region 55a exposed to the outside. The electrode layer 55 is a layer made of Au (first metal). The electrode layer 55 is formed, for example, by sputtering Au. A thickness of the electrode layer 55 is, for example, approximately 150 nm.

The additional layer 56 is formed on the electrode layer 55 to extend along the second end surface 3b when viewed in the Z-axis direction. Namely, the additional layer 56 is disposed on the electrode layer 55, and is located on the second end surface 3b side with respect to the region 55a of the electrode layer 55. When viewed in the Z-axis direction, both side surfaces of the additional layer 56 facing each other in the X-axis direction coincide with both the respective side surfaces of the electrode layer 55 facing each other in the X-axis direction. When viewed in the Z-axis direction, a side surface of the additional layer 56 located on the second end surface 3b side in the Y-axis direction coincides with the second end surface 3b. The additional layer 56 is a layer made of Ti (second metal). The additional layer 56 is formed, for example, by sputtering Ti. A thickness of the additional layer 56 is, for example, approximately 50 nm.

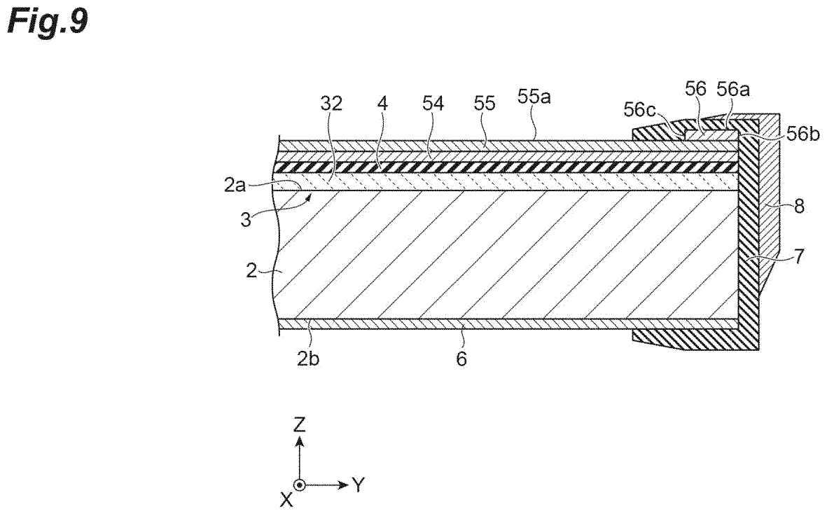

In the first electrode 5 configured as described above, as shown in FIGS. 8A and 9, the additional layer 56 has a region (second region) 56a. The region 56a is a surface on an opposite side of the additional layer 56 from the semiconductor substrate 2, and is located on the second end surface 3b side with respect to the region 55a of the electrode layer 55 in the Y-axis direction. An edge portion 56b on the second end surface 3b side of the additional layer 56 is located on the second end surface 3b side with respect to the region 55a of the electrode layer 55 in the Y-axis direction. In the second embodiment, an edge portion on the second end surface 3b side of the region 56a of the additional layer 56 corresponds to the edge portion 56b of the additional layer 56, and is located on a plane including the second end surface 3b. The region 55a of the electrode layer 55 is in a relationship of intersection with a region 56c on an opposite side of the side surface of the additional layer 56 from the second end surface 3b. Incidentally, FIG. 9 is a cross-sectional view of the quantum cascade laser element 1B at a portion on one side in the X-axis direction with respect to the ridge portion 30.

As described above, the electrode layer 55 is a layer made of Au (first metal), and the additional layer 56 is a layer made of Ti (second metal). Ti is a metal having a higher ionization tendency than that of Au. The additional layer 56 has a property of having a higher force of adhesion to an oxide than that of the electrode layer 55. The electrode layer 55 has a property of being less likely to be oxidized than the additional layer 56.

As shown in FIGS. 2, 8B, and 9, the insulating film 7 is formed on the second end surface 3b. In the second embodiment, the insulating film 7 reaches the region 5r of the first electrode 5 from the second end surface 3b via the region 56a and the region 56c of the additional layer 56, and reaches the region 6r of the second electrode 6 from the second end surface 3b via the side surface 2c of the semiconductor substrate 2. As described above, the insulating film 7 reaches the electrode layer 55 from the second end surface 3b via the region 56a and the region 56c of the additional layer 56, and is in contact with the region 56a of the additional layer 56, with the region 56c of the additional layer 56, and with the region 55a of the electrode layer 55. In the second embodiment, the insulating film 7 covers the entirety of the region 56a of the additional layer 56. Incidentally, in FIG. 8B, the metal film 8 is not shown.

As shown in FIGS. 2, 8C, and 9, the metal film 8 is formed on the insulating film 7 to overlap at least a part of the active layer 31 when viewed in the optical waveguide direction A. In the second embodiment, the metal film 8 includes the entirety of the active layer 31 when viewed in the optical waveguide direction A, and is formed only on the insulating film 7 to extend along the second end surface 3b of the semiconductor laminate 3, along the side surface 2c of the semiconductor substrate 2, and along the region 56a of the additional layer 56. A width of the metal film 8 in the optical waveguide direction A on the ridge portion 30 (namely, on the surface 30a of the ridge portion 30 (refer to FIG. 1)) is smaller than a width of the metal film 8 in the optical waveguide direction A on portions on both sides of the ridge portion 30 (namely, on the surface 32a of the lower cladding layer 32 (refer to FIG. 1)). In the second embodiment, the width of the metal film 8 in the optical waveguide direction A on the ridge portion 30 is 0.

Incidentally, when viewed in the Y-axis direction, an edge portion on a second electrode 6 side of the metal film 8 does not reach an edge portion on the second electrode 6 side of the insulating film 7. In the oblique sputtering of Au as shown in FIG. 6B, the metal film 8 described above is formed by obliquely performing sputtering of Au in a state where the surface of the insulating layer 700 formed on the surface of the portion 210 of each of the laser bars 200 is recessed with respect to a plane including the end surfaces 500b of the dummy bars 500 adjacent to each other.

In the second embodiment, the insulating film 7 is an Al₂O₃ film or a CeO₂ film, and the metal film 8 is an Au film. When the semiconductor laminate 3 is configured to oscillate laser light having a central wavelength of any value of 4 to 7.5 μm, it is preferable that the insulating film 7 is an Al₂O₃ film having a property of transmitting light having a wavelength of 4 to 7.5 μm. When the semiconductor laminate 3 is configured to oscillate laser light having a central wavelength of any value of 7.5 to 11 μm, it is preferable that the insulating film 7 is a CeO₂ film having a property of transmitting light having a wavelength of 7.5 to 11 μm. When the semiconductor laminate 3 is configured to oscillate laser light having a central wavelength of any value of 4 to 11 μm, it is preferable that the metal film 8 is an Au film that effectively functions as a reflection film for reflecting light having a wavelength of 4 to 11 μm.

As described above, in the quantum cascade laser element 1B, the first electrode 5 includes the electrode layer 55 made of Au, and the additional layer 56 made of Ti having a higher ionization tendency than that of Au, and the insulating film 7 formed on the second end surface 3b of the semiconductor laminate 3 reaches the region 56a of the additional layer 56 from the second end surface 3b. Accordingly, it is possible to sufficiently ensure adhesion between the additional layer 56 and the insulating film 7 in the region 56a located on the second end surface 3b side with respect to the region 55a, while suppressing oxidation of the electrode layer 55 in the region 55a exposed to the outside. Therefore, according to the quantum cascade laser element 1B, it is possible to suppress peeling of the insulating film 7 off from the second end surface 3b of the semiconductor laminate 3.

Particularly, in the quantum cascade laser element 1B, since the insulating film 7 reaches the electrode layer 55 in a state where the insulating film 7 covers the entirety of the region 56a of the additional layer 56, it is possible to reliably suppress oxidation of the additional layer 56.

In the quantum cascade laser element 1B, the additional layer 56 is disposed on the electrode layer 55, and the additional layer 56 is located on the second end surface 3b side with respect to the region 55a of the electrode layer 55. Accordingly, the region 56a for ensuring adhesion between the additional layer 56 and the insulating film 7 can be reliably provided in the vicinity of the second end surface 3b side.

In the quantum cascade laser element 1B, the insulating film 7 reaches the electrode layer 55 via the region 56c of the side surface of the additional layer 56, the region 56c being in a relationship of intersection with the region 55a of the electrode layer 55. Accordingly, since a part of the insulating film 7 comes into contact with at least a pair of regions that are in a relationship of intersection in the first electrode 5, it is possible to more sufficiently ensure adhesion between the first electrode 5 and the insulating film 7.

In the quantum cascade laser element 1B, the metal film 8 is formed on the insulating film 7 to overlap at least a part of the active layer 31 when viewed in the optical waveguide direction A. Accordingly, it is possible to obtain an efficient light output by causing the metal film 8 on the second end surface 3b to function as a reflection film, and by causing the first end surface 3a opposite the second end surface 3b to function as a light-emitting surface.

In the quantum cascade laser element 1B, the semiconductor laminate 3 includes the ridge portion 30. Accordingly, it is possible to reduce electric power consumption of the quantum cascade laser element 1B by reducing a driving current of the quantum cascade laser element 1B.

In the quantum cascade laser element 1B, the width of the metal film 8 in the optical waveguide direction A on the ridge portion 30 is 0. Accordingly, it is possible to reliably suppress occurrence of a short circuit in the ridge portion 30 caused by the metal film 8. Incidentally, when the width of the metal film 8 in the optical waveguide direction A on the ridge portion 30 is smaller than the width of the metal film 8 in the optical waveguide direction A on the portions on both sides of the ridge portion 30, it is possible to suppress occurrence of a short circuit in the ridge portion 30 caused by the metal film 8.

In the quantum cascade laser element 1B, the insulating film 7 is an Al₂O₃ film or a CeO₂ film. When the insulating film 7 is an Al₂O₃ film, it is possible to ensure a property of transmitting laser light having a central wavelength of 7.5 μm or less. When the insulating film 7 is a CeO₂ film, it is possible to ensure a property of transmitting laser light having a central wavelength of 7.5 μm or more.

### Modification Examples

The present disclosure is not limited to the first embodiment and the second embodiment described above. For example, a known quantum cascade structure can be applied to the active layer 31. In addition, a known lamination structure can be applied to the semiconductor laminate 3. As one example, in the semiconductor laminate 3, the upper guide layer may not have a diffraction grating structure functioning as a distributed feedback structure. In addition, the ridge portion 30 may not be formed in the semiconductor laminate 3.

In addition, in the first embodiment, the first foundation layer 51 is a layer made of Ti (second metal), and the electrode layer 53 is a layer made of Au (first metal), but the first metal is not limited to Au, and the second metal is not limited to Ti. In the first embodiment, the electrode layer 53 may be a layer made of the first metal, and the first foundation layer 51 may be a layer made of the second metal having a higher ionization tendency than that of the first metal. The first foundation layer 51 may be, for example, a layer made of Cr (second metal). The electrode layer 53 may be, for example, a layer made of Pt (first metal).

In addition, in the second embodiment, the electrode layer 55 is a layer made of Au (first metal), and the additional layer 56 is a layer made of Ti (second metal), but the first metal is not limited to Au, and the second metal is not limited to Ti. In the second embodiment, the electrode layer 55 may be a layer made of the first metal, and the additional layer 56 may be a layer made of the second metal having a higher ionization tendency than that of the first metal. The electrode layer 55 may be, for example, a layer made of Pt (first metal). The additional layer 56 may be, for example, a layer made of Cr (second metal).

In addition, in the first embodiment, the electrode layer 53 may be directly formed on the first foundation layer 51 (namely, without another layer interposed therebetween), or the electrode layer 53 may be indirectly formed on the first foundation layer 51 (namely, with another layer interposed therebetween). In addition, in the second embodiment, the additional layer 56 may be directly formed on the electrode layer 55, or the additional layer 56 may be indirectly formed on the electrode layer 55. For example, when a layer made of Ti and a layer made of Au are laminated, the layer made of Ti and the layer made of Au may be directly laminated, or the layer made of Ti and the layer made of Au may be indirectly laminated with a layer made of Pt interposed therebetween. Incidentally, when the first metal layer having the first region exposed to the outside is made of Au, and the second metal layer having the second region located on one end surface side with respect to the first region is made of Ti or Cr, it is possible to reliably suppress oxidation of the first metal layer in the first region exposed to the outside. In addition, it is possible to sufficiently ensure adhesion between the second metal layer and the first metal layer, and it is possible to sufficiently ensure adhesion between the second metal layer and the insulating film.

In addition, in the first embodiment, the edge portion on the second end surface 3b side of the region 51a of the first foundation layer 51, and the edge portion 51b of the first foundation layer 51 may be located inside a plane including the second end surface 3b. In addition, in the second embodiment, the edge portion on the second end surface 3b side of the region 56a of the additional layer 56, and the edge portion 56b of the additional layer 56 may be located inside a plane including the second end surface 3b.

In addition, in the first embodiment, the first electrode 5 may not include the electrode layer 53, and the second foundation layer 52 may function as the first metal layer having the first region exposed to the outside. In other words, in the second embodiment, the first electrode may not include the additional layer 56, and the foundation layer 54 may function as the second metal layer having the second region located on the second end surface 3b side with respect to the region 55a of the electrode layer 55, by forming the electrode layer 55 such that the edge portion on the second end surface 3b side of the electrode layer 55 is separated from the second end surface 3b when viewed in the Z-axis direction.

In addition, in the first embodiment, the insulating film 7 may not cover a part of the region 51a of the first foundation layer 51. In addition, in the second embodiment, the insulating film 7 may not cover a part of the region 56a of the additional layer 56. In addition, the insulating film 7 is not limited to an Al₂O₃ film or a CeO₂ film. In the first embodiment, when the insulating film 7 is a film made of an oxide, it is possible to sufficiently ensure adhesion between the first foundation layer 51 and the insulating film 7. In the second embodiment, when the insulating film 7 is a film made of an oxide, it is possible to sufficiently ensure adhesion between the additional layer 56 and the insulating film 7. The metal film 8 is not limited to an Au film. For example, the metal film 8 may be formed by laminating a Ti film and an Au film in order from the insulating film 7 side.

In addition, in the first and second embodiments, the metal film 8 may not be formed on the insulating film 7. In that case, the insulating film 7 may function as at least a part of a protective film or may function as at least a part of an anti-reflection film. In addition, in the first and second embodiments, the insulating film 7 is formed on the second end surface 3b of the semiconductor laminate 3, but the insulating film 7 may be formed on at least one end surface of the first end surface 3a and the second end surface 3b of the semiconductor laminate 3.

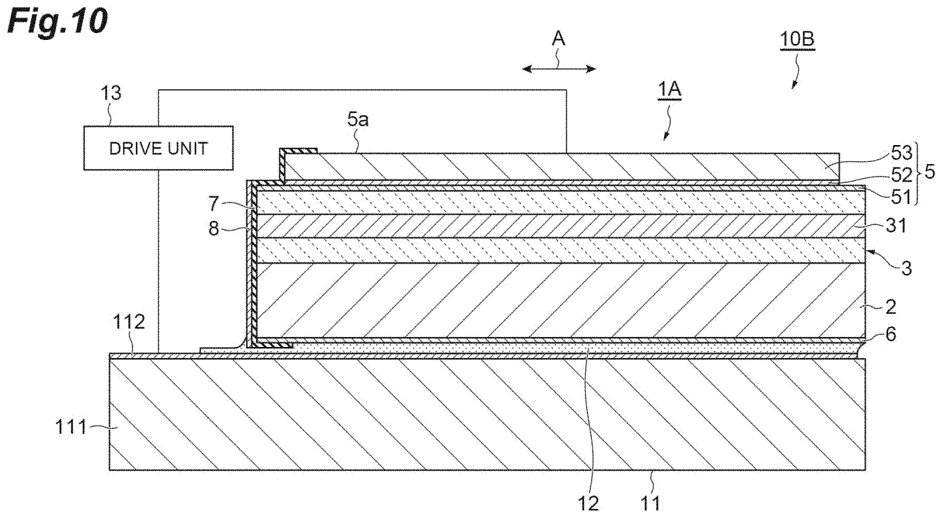

In addition, as shown in FIG. 10, the quantum cascade laser element 1A may be supported by the support portion 11 in a state where the semiconductor substrate 2 is located on the support portion 11 side with respect to the semiconductor laminate 3 (namely, an epi-side-up state). In a quantum cascade laser device 10B shown in FIG. 10, the joining member 12 joins the electrode pad 112 of the support portion 11 and the second electrode 6 of the quantum cascade laser element 1A in the epi-side-up state. Incidentally, the quantum cascade laser element 1B also may be supported by the support portion 11 in the epi-side-down state, or may be supported by the support portion 11 in the epi-side-up state. In addition, the drive unit 13 may drive each of the quantum cascade laser elements 1A and 1B such that each of the quantum cascade laser elements 1A and 1B oscillates laser light in a pulsed manner.

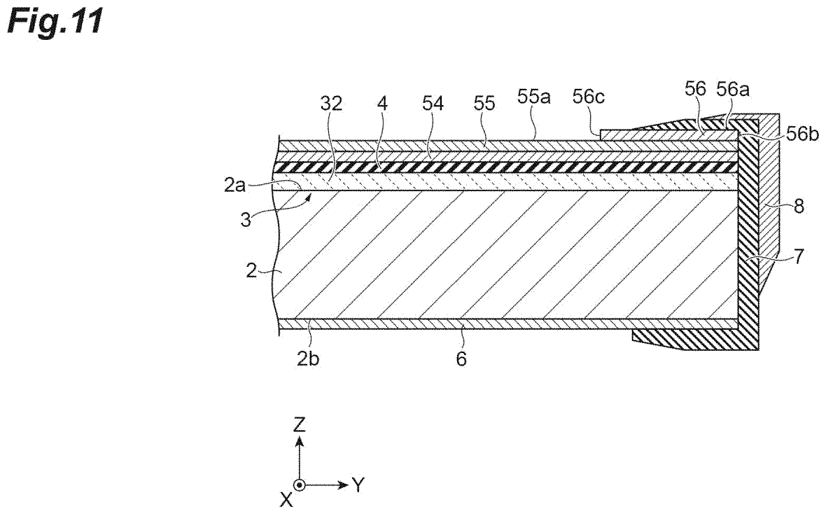

In addition, in the quantum cascade laser element 1B, as shown in FIG. 11, the insulating film 7 reaches the region 56a of the additional layer 56 from the second end surface 3b, and may not reach the region 5r of the first electrode 5. Namely, when the insulating film 7 reaches the additional layer 56, the insulating film 7 may not reach the electrode layer 55. In this case, since an edge portion of the insulating film 7 is located on the additional layer 56, it is possible to more reliably suppress peeling of the edge portion of the insulating film 7 compared to when the edge portion of the insulating film 7 is located on the electrode layer 55.

A quantum cascade laser element according to one aspect of the present disclosure includes: a semiconductor substrate; a semiconductor laminate formed on the semiconductor substrate, including an active layer having a quantum cascade structure, and having a first end surface and a second end surface facing each other in an optical waveguide direction; a first electrode formed on a surface on an opposite side of the semiconductor laminate from the semiconductor substrate; a second electrode formed on a surface on an opposite side of the semiconductor substrate from the semiconductor laminate; and an insulating film formed on at least one end surface of the first end surface and the second end surface. The first electrode includes a first metal layer made of a first metal, and a second metal layer made of a second metal having a higher ionization tendency than an ionization tendency of the first metal. The first metal layer has a first region exposed to an outside. The second metal layer has a second region located on one end surface side with respect to the first region. The insulating film reaches the second region from the one end surface.

In the quantum cascade laser element, the first electrode includes the first metal layer made of the first metal, and the second metal layer made of the second metal having a higher ionization tendency than that of the first metal, and the insulating film formed on the one end surface of the semiconductor laminate reaches the second region of the second metal layer from the one end surface.

Accordingly, it is possible to sufficiently ensure adhesion between the second metal layer and the insulating film in the second region located on the one end surface side with respect to the first region, while suppressing oxidation of the first metal layer in the first region exposed to the outside. Therefore, according to the quantum cascade laser element, it is possible to suppress peeling of the insulating film off from the end surface of the semiconductor laminate.

In the quantum cascade laser element according to one aspect of the present disclosure, the first metal layer may be disposed on the second metal layer, and an edge portion on the one end surface side of the second metal layer may be located on the one end surface side with respect to the first region. According to this aspect, the second region for ensuring adhesion between the second metal layer and the insulating film can be reliably provided in the vicinity of the one end surface side.

In the quantum cascade laser element according to one aspect of the present disclosure, the insulating film may reach a region of a side surface of the first metal layer, the region being in a relationship of intersection with the second region. According to this aspect, since a part of the insulating film comes into contact with at least a pair of regions that are in a relationship of intersection in the first electrode, it is possible to more sufficiently ensure adhesion between the first electrode and the insulating film.

In the quantum cascade laser element according to one aspect of the present disclosure, the second metal layer may be disposed on the first metal layer, and may be located on the one end surface side with respect to the first region. According to this aspect, the second region for ensuring adhesion between the second metal layer and the insulating film can be reliably provided in the vicinity of the one end surface side.

In the quantum cascade laser element according to one aspect of the present disclosure, the insulating film may reach the first metal layer via a region of a side surface of the second metal layer, the region being in a relationship of intersection with the first region. According to this aspect, since a part of the insulating film comes into contact with at least a pair of regions that are in a relationship of intersection in the first electrode, it is possible to more sufficiently ensure adhesion between the first electrode and the insulating film.

The quantum cascade laser element according to one aspect of the present disclosure may further include a metal film formed on the insulating film to overlap at least a part of the active layer when viewed in the optical waveguide direction. According to this aspect, it is possible to obtain an efficient light output by causing the metal film on the one end surface to function as a reflection film, and by causing the end surface opposite the one end surface to function as a light-emitting surface.

In the quantum cascade laser element according to one aspect of the present disclosure, the semiconductor laminate may include a ridge portion, and a width of the metal film in the optical waveguide direction on the ridge portion may be smaller than a width of the metal film in the optical waveguide direction on portions of both sides of the ridge portion. According to this aspect, it is possible to suppress occurrence of a short circuit in the ridge portion caused by the metal film, while reducing electric power consumption of the quantum cascade laser element by reducing a driving current of the quantum cascade laser element.

In the quantum cascade laser element according to one aspect of the present disclosure, the width of the metal film in the optical waveguide direction on the ridge portion may be 0. According to this aspect, it is possible to reliably suppress occurrence of a short circuit in the ridge portion caused by the metal film.

In the quantum cascade laser element according to one aspect of the present disclosure, the first metal may be Au, and the second metal may be Ti or Cr. According to this aspect, it is possible to reliably suppress oxidation of the first metal layer in the first region exposed to the outside. In addition, it is possible to sufficiently ensure adhesion between the second metal layer and the first metal layer, and it is possible to sufficiently ensure adhesion between the second metal layer and the insulating film.

In the quantum cascade laser element according to one aspect of the present disclosure, the insulating film may be an Al₂O₃ film or a CeO₂ film. When the insulating film is an Al₂O₃ film, it is possible to ensure a property of transmitting laser light having a central wavelength of 7.5 μm or less. When the insulating film is a CeO₂ film, it is possible to ensure a property of transmitting laser light having a central wavelength of 7.5 μm or more.

A quantum cascade laser device according to one aspect of the present disclosure includes: the quantum cascade laser element; and a drive unit configured to drive the quantum cascade laser element.

According to the quantum cascade laser device, it is possible to suppress peeling of the insulating film off from the end surface of the semiconductor laminate in the quantum cascade laser element.

The quantum cascade laser device according to one aspect of the present disclosure may further include: a support portion supporting the quantum cascade laser element; and a joining member joining an electrode pad included in the support portion, and the first electrode in a state where the semiconductor laminate is located on a support portion side with respect to the semiconductor substrate. According to this aspect, heat generated in the active layer can be efficiently released to the support portion side.

In the quantum cascade laser device according to one aspect of the present disclosure, the drive unit may drive the quantum cascade laser element such that the quantum cascade laser element continuously oscillates laser light. When the quantum cascade laser element continuously oscillates laser light, the amount of heat generated in the active layer is increased compared to when the quantum cascade laser element oscillates laser light in a pulsed manner, so that the above-described configuration of the quantum cascade laser element is particularly effective.

According to the present disclosure, it is possible to provide the quantum cascade laser element and the quantum cascade laser device capable of suppressing peeling of the insulating film off from the end surface of the semiconductor laminate.

What is claimed is:

1. A quantum cascade laser element comprising:
a semiconductor substrate;
a semiconductor laminate formed on the semiconductor substrate, including an active layer having a quantum cascade structure, and having a first end surface and a second end surface facing each other in an optical waveguide direction;
a first electrode formed on a surface on an opposite side of the semiconductor laminate from the semiconductor substrate;
a second electrode formed on a surface on an opposite side of the semiconductor substrate from the semiconductor laminate; and
an insulating film formed on at least one end surface of the first end surface and the second end surface,
wherein the first electrode includes a first metal layer made of a first metal, and a second metal layer made of a second metal having a higher ionization tendency than an ionization tendency of the first metal,
the first metal layer has a first region exposed to an outside,
the second metal layer has a second region located on one end surface side with respect to the first region, and
the insulating film reaches the second region from the one end surface.

2. The quantum cascade laser element according to claim 1,
wherein the first metal layer is disposed on the second metal layer, and
an edge portion on the one end surface side of the second metal layer is located on the one end surface side with respect to the first region.

3. The quantum cascade laser element according to claim 2,
wherein the insulating film reaches a region of a side surface of the first metal layer, the region being in a relationship of intersection with the second region.

4. The quantum cascade laser element according to claim 1,
wherein the second metal layer is disposed on the first metal layer, and is located on the one end surface side with respect to the first region.

5. The quantum cascade laser element according to claim 4,
wherein the insulating film reaches the first metal layer via a region of a side surface of the second metal layer, the region being in a relationship of intersection with the first region.

6. The quantum cascade laser element according to claim 1, further comprising:
a metal film formed on the insulating film to overlap at least a part of the active layer when viewed in the optical waveguide direction.

7. The quantum cascade laser element according to claim 6,
wherein the semiconductor laminate includes a ridge portion, and
a width of the metal film in the optical waveguide direction on the ridge portion is smaller than a width of the metal film in the optical waveguide direction on portions of both sides of the ridge portion.

8. The quantum cascade laser element according to claim 7,
wherein the width of the metal film in the optical waveguide direction on the ridge portion is 0.

9. The quantum cascade laser element according to claim 1,
wherein the first metal is Au, and
the second metal is Ti or Cr.

10. The quantum cascade laser element according to claim 1,
wherein the insulating film is an Al₂O₃ film or a CeO₂ film.

11. A quantum cascade laser device comprising:
the quantum cascade laser element according to claim 1; and
a drive unit configured to drive the quantum cascade laser element.

12. The quantum cascade laser device according to claim 11, further comprising:
a support portion supporting the quantum cascade laser element; and
a joining member joining an electrode pad included in the support portion, and the first electrode in a state where the semiconductor laminate is located on a support portion side with respect to the semiconductor substrate.

13. The quantum cascade laser device according to claim 11,
wherein the drive unit drives the quantum cascade laser element such that the quantum cascade laser element continuously oscillates laser light.
